(19) United States
(12) Patent Application Publication
(10) Pub. No.: US 2004/0227238 A1
(43) Pub. Date: Nov. 18, 2004

(54) Electronic device and method of manufacturing the same, circuit board, and electronic instrument

(75) Inventor: Nobuaki Hashimoto, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/788,295

(22) Filed: Mar. 1, 2004

(30) Foreign Application Priority Data
Mar. 13, 2003 (JP) 2003-068280

(51) Int. Cl. H01L 23/48

(52) U.S. Cl. 257/738

(57) ABSTRACT

An electronic device having: a substrate having an interconnecting pattern; a first chip component which has a first electrode and is mounted on a first surface of the substrate; a second chip component which has a second electrode and is mounted on a second surface of the substrate; a first insulating portion which is formed of resin and disposed adjacent to the first chip component; a second insulating portion which is formed of resin and disposed adjacent to the second chip component; a first interconnecting line formed to extend from over the first electrode, passing over the first insulating portion, to reach over the interconnecting pattern; and a second interconnecting line formed to extend from over the second electrode, passing over the second insulating portion, to reach over the interconnecting pattern.

Japanese Patent Application No. 2003-68280, filed on Mar. 13, 2003, is hereby incorporated by reference in its entirety.

### BACKGROUND OF THE INVENTION

The present invention relates to an electronic device and method of manufacturing the electronic device, to a circuit board, and to an electronic instrument.

Conventionally, in COB (Chip On Board) mounting, since heat is applied, the substrate is required to be heat resistant, and therefore a thermoplastic substrate cannot be used, making it difficult to use an inexpensive substrate. Moreover, since heat and external mechanical forces are applied to the semiconductor chip, it is difficult to avoid faults arising from the resultant stress. Furthermore, when wire bonding is applied, there are limits on the length of the wire, and therefore a general-purpose substrate cannot be used. Even when face-down bonding is applied, since it is necessary to use a special substrate depending on the semiconductor chip electrode layout, a general-purpose substrate cannot be used.

### BRIEF SUMMARY OF THE INVENTION

According to a first aspect of the present invention, there is provided an electronic device comprising:

a substrate having an interconnecting pattern;

a first chip component which has a first electrode and is mounted on a first surface of the substrate;

a second chip component which has a second electrode and is mounted on a second surface of the substrate;

a first insulating portion which is formed of resin and disposed laterally to the first chip component;

a second insulating portion which is formed of resin and disposed laterally to the second chip component;

a first interconnecting line formed to extend from over the first electrode, passing over the first insulating portion, to reach over the interconnecting pattern; and

a second interconnecting line formed to extend from over the second electrode, passing over the second insulating portion, to reach over the interconnecting pattern.

According to a second aspect of the present invention, there is provided an electronic device comprising:

a substrate having an interconnecting pattern;

a first chip component which has a first electrode and is mounted on a first surface of the substrate;

a second chip component which has a second electrode and is mounted on a second surface of the substrate;

a first insulating portion which is disposed laterally to the first chip component and has a first inclined surface descending outward from the first chip component;

a second insulating portion which is disposed laterally to the second chip component and has a second inclined surface descending outward from the second chip component;

a first interconnecting line formed to extend from over the first electrode, passing over the first insulating portion, to reach over the interconnecting pattern; and

a second interconnecting line formed to extend from over the second electrode, passing over the second insulating portion, to reach over the interconnecting pattern.

According to a third aspect of the present invention, there is provided an electronic device comprising:

a substrate having an interconnecting pattern;

a first chip component which has a first electrode and is mounted on the substrate;

a second chip component which has a second electrode and is disposed on the side of a surface of the substrate on which the first chip component is mounted, to overlie the first chip component;

a first insulating portion which is formed of resin and disposed laterally to the first chip component;

a second insulating portion which is formed of resin and disposed laterally to the second chip component;

a first interconnecting line formed to extend from over the first electrode, passing over the first insulating portion, to over the interconnecting pattern; and

a second interconnecting line formed to extend from over the second electrode, passing over the second insulating portion, and electrically connected to the interconnecting pattern.

According to a fourth aspect of the present invention, there is provided an electronic device comprising:

a substrate having an interconnecting pattern;

a first chip component which has a first electrode and is mounted on the substrate;

a second chip component which has a second electrode and is disposed on the side of a surface of the substrate on which the first chip component is mounted, to overlie the first chip component;

a first insulating portion which is disposed laterally to the first chip component and has a first inclined surface descending outward from the first chip component;

a second insulating portion which is disposed laterally to the second chip component and has a second inclined surface descending outward from the second chip component;

a first interconnecting line formed to extend from over the first electrode, passing over the first insulating portion, to over the interconnecting pattern; and

a second interconnecting line formed to extend from over the second electrode, passing over the second insulating portion, and electrically connected to the interconnecting pattern.

According to a fifth aspect of the present invention, there is provided a method of manufacturing an electronic device, comprising:

mounting a first chip component having a first electrode on a first surface of a substrate in which an interconnecting pattern is formed;

mounting a second chip component having a second electrode on a second surface of the substrate;

forming a first insulating portion of resin laterally to the first chip component;

forming a second insulating portion of resin laterally to the second chip component;

forming a first interconnecting line to extend from over the first electrode, passing over the first insulating portion, to reach over the interconnecting pattern; and

forming a second interconnecting line to extend from over the second electrode, passing over the second insulating portion, to reach over the interconnecting pattern.

According to a sixth aspect of the present invention, there is provided a method of manufacturing an electronic device, comprising:

mounting a first chip component having a first electrode on a first surface of a substrate in which an interconnecting pattern is formed;

mounting a second chip component having a second electrode on a second surface of the substrate;

forming a first insulating portion laterally to the first chip component so as to have a first inclined surface descending outward from the first chip component;

forming a second insulating portion laterally to the second chip component so as to have a second inclined surface descending outward from the second chip component;

forming a first interconnecting line to extend from over the first electrode, passing over the first insulating portion, to reach over the interconnecting pattern; and

forming a second interconnecting line to extend from over the second electrode, passing over the second insulating portion, to reach over the interconnecting pattern.

According to a seventh aspect of the present invention, there is provided a method of manufacturing an electronic device, comprising:

mounting a first chip component having a first electrode on a substrate in which an interconnecting pattern is formed;

disposing a second chip component having a second electrode, on the side of a surface of the substrate on which the first chip component is mounted, to overlie the first chip component;

forming a first insulating portion of resin laterally to the first chip component;

forming a second insulating portion of resin laterally to the second chip component;

forming a first interconnecting line to extend from over the first electrode, passing over the first insulating portion, to reach over the interconnecting pattern; and

forming a second interconnecting line to extend from over the second electrode, passing over the second insulating portion, and electrically connected to the interconnecting pattern.

According to an eighth aspect of the present invention, there is provided a method of manufacturing an electronic device, comprising:

mounting a first chip component having a first electrode on a substrate in which an interconnecting pattern is formed;

disposing a second chip component having a second electrode, on the side of a surface of the substrate on which the first chip component is mounted, to overlie the first chip component;

forming a first insulating portion laterally to the first chip component so as to have a first inclined surface descending outward from the first chip component;

forming a second insulating portion laterally to the second chip component so as to have a second inclined surface descending outward from the second chip component;

forming a first interconnecting line to extend from over the first electrode, passing over the first insulating portion, to reach over the interconnecting pattern; and

forming a second interconnecting line to extend from over the second electrode, passing over the second insulating portion, and electrically connected to the interconnecting pattern.

According to a ninth aspect of the present invention, there is provided a circuit board on which any one of the above described electronic devices is mounted.

According to a tenth aspect of the present invention, there is provided an electronic instrument comprising any one of the above described electronic device.

### BRIEF DESCRIPTION OF THE SEVERAL VIEWS OF THE DRAWING

FIG. 1 is a cross-sectional view taken along I-I line in FIG. 2.

FIG. 2 is a plan view showing an electronic device according to a first embodiment of the present invention.

FIGS. 3A to 3C illustrate a method of manufacturing an electronic device according to the first embodiment of the present invention.

FIG. 4 illustrates an electronic device according to a second embodiment of the present invention.

FIG. 5 illustrates a modification of the electronic device according to the embodiments of the present invention.

FIG. 6 illustrates a modification of the electronic device according to the embodiments of the present invention.

FIG. 7 illustrates a modification of the electronic device according to the embodiments of the present invention.

FIG. 8 illustrates a modification of the electronic device according to the embodiments of the present invention.

FIG. 9 illustrates a modification of the electronic device according to the embodiments of the present invention.

FIG. 10A and FIG. 10B illustrate the method of manufacturing the chip component shown in FIG. 9.

FIG. 11 illustrates a modification of the electronic device according to the embodiments of the present invention.

FIG. 12 illustrates a modification of the electronic device according to the embodiments of the present invention.

FIG. 13 shows a circuit board on which is mounted the electronic device according to the embodiments of the present invention.

FIG. 14 shows an electronic instrument having the electronic device according to the embodiments of the present invention.

FIG. 15 shows an electronic instrument having the electronic device according to the embodiments of the present invention.

### DETAILED DESCRIPTION OF THE EMBODIMENTS

The objective of the embodiments of the present invention is to reduce the requirement for a substrate to be heat resistant, and to reduce the stress generated in a semiconductor chip, thus enabling the use of a general-purpose substrate.

(1) According to one embodiment of the present invention, there is provided an electronic device comprising:

a substrate having an interconnecting pattern;

a first chip component which has a first electrode and is mounted on a first surface of the substrate;

a second chip component which has a second electrode and is mounted on a second surface of the substrate;

a first insulating portion which is formed of resin and disposed laterally to the first chip component;

a second insulating portion which is formed of resin and disposed laterally to the second chip component;

a first interconnecting line formed to extend from over the first electrode, passing over the first insulating portion, to reach over the interconnecting pattern; and

a second interconnecting line formed to extend from over the second electrode, passing over the second insulating portion, to reach over the interconnecting pattern.

When electrically connecting the first or second electrode to the interconnecting pattern, this embodiment of the present invention enables to avoid heating to a high temperature, such as is carried out in wire bonding or face-down bonding. Therefore, the requirements for heat resistance of the substrate can be reduced, and the generation of stress in the first and second chip components can be reduced. Since the first and second interconnecting lines can be freely formed, the use of a general-purpose substrate is possible.

(2) According to one embodiment of the present invention, there is provided an electronic device comprising:

a substrate having an interconnecting pattern;

a first chip component which has a first electrode and is mounted on a first surface of the substrate;

a second chip component which has a second electrode and is mounted on a second surface of the substrate;

a first insulating portion which is disposed laterally to the first chip component and has a first inclined surface descending outward from the first chip component;

a second insulating portion which is disposed laterally to the second chip component and has a second inclined surface descending outward from the second chip component;

a first interconnecting line formed to extend from over the first electrode, passing over the first insulating portion, to reach over the interconnecting pattern; and

a second interconnecting line formed to extend from over the second electrode, passing over the second insulating portion, to reach over the interconnecting pattern.

When electrically connecting the first or second electrode to the interconnecting pattern, this embodiment of the present invention enables to avoid heating to a high temperature, such as is carried out in wire bonding or face-down bonding. Therefore, the requirements for heat resistance of the substrate can be reduced, and the generation of stress in the first and second chip components can be reduced. Since the first and second interconnecting lines can be freely formed, the use of a general-purpose substrate is possible.

(3) According to one embodiment of the present invention, there is provided an electronic device comprising:

a substrate having an interconnecting pattern;

a first chip component which has a first electrode and is mounted on the substrate;

a second chip component which has a second electrode and is disposed on the side of a surface of the substrate on which the first chip component is mounted, to overlie the first chip component;

a first insulating portion which is formed of resin and disposed laterally to the first chip component;

a second insulating portion which is formed of resin and disposed laterally to the second chip component;

a first interconnecting line formed to extend from over the first electrode, passing over the first insulating portion, to over the interconnecting pattern; and

a second interconnecting line formed to extend from over the second electrode, passing over the second insulating portion, and electrically connected to the interconnecting pattern.

When electrically connecting the first or second electrode to the interconnecting pattern, this embodiment of the present invention enables to avoid heating to a high temperature, such as is carried out in wire bonding or face-down bonding. Therefore, the requirements for heat resistance of the substrate can be reduced, and the generation of stress in the first and second chip components can be reduced. Since the first and second interconnecting lines can be freely formed, the use of a general-purpose substrate is possible.

(4) According to one embodiment of the present invention, there is provided an electronic device comprising:

a substrate having an interconnecting pattern;

a first chip component which has a first electrode and is mounted on the substrate;

a second chip component which has a second electrode and is disposed on the side of a surface of the substrate on which the first chip component is mounted, to overlie the first chip component;

a first insulating portion which is disposed laterally to the first chip component and has a first inclined surface descending outward from the first chip component;

a second insulating portion which is disposed laterally to the second chip component and has a second inclined surface descending outward from the second chip component;

a first interconnecting line formed to extend from over the first electrode, passing over the first insulating portion, to over the interconnecting pattern; and

a second interconnecting line formed to extend from over the second electrode, passing over the second insulating portion, and electrically connected to the interconnecting pattern.

When electrically connecting the first or second electrode to the interconnecting pattern, this embodiment of the present invention enables to avoid heating to a high temperature, such as is carried out in wire bonding or face-down bonding. Therefore, the requirements for heat resistance of the substrate can be reduced, and the generation of stress in the first and second chip components can be reduced. Since the first and second interconnecting lines can be freely formed, the use of a general-purpose substrate is possible.

(5) The electronic device may further comprise an insulating layer part of which is interposed between the first and second chip components, wherein:

the second insulating portion may be formed above the insulating layer; and

the second interconnecting line may be formed to pass over the insulating layer.

(6) The electronic device may further comprise a conductive portion interposed between the second interconnecting line and the interconnecting pattern.

(7) In the electronic device, a penetrating hole may be formed in the insulating layer, and the conductive portion may be formed in the penetrating hole.

(8) According to one embodiment of the present invention, there is provided a method of manufacturing an electronic device, comprising:

mounting a first chip component having a first electrode on a first surface of a substrate in which an interconnecting pattern is formed;

mounting a second chip component having a second electrode on a second surface of the substrate;

forming a first insulating portion of resin laterally to the first chip component;

forming a second insulating portion of resin laterally to the second chip component;

forming a first interconnecting line to extend from over the first electrode, passing over the first insulating portion, to reach over the interconnecting pattern; and

forming a second interconnecting line to extend from over the second electrode, passing over the second insulating portion, to reach over the interconnecting pattern.

When electrically connecting the first or second electrode to the interconnecting pattern, this embodiment of the present invention enables to avoid heating to a high temperature, such as is carried out in wire bonding or face-down bonding. Therefore, the requirements for heat resistance of the substrate can be reduced, and the generation of stress in the first and second chip components can be reduced. Since the first and second interconnecting lines can be freely formed, the use of a general-purpose substrate is possible.

(9) According to one embodiment of the present invention, there is provided a method of manufacturing an electronic device, comprising:

mounting a first chip component having a first electrode on a first surface of a substrate in which an interconnecting pattern is formed;

mounting a second chip component having a second electrode on a second surface of the substrate;

forming a first insulating portion laterally to the first chip component so as to have a first inclined surface descending outward from the first chip component;

forming a second insulating portion laterally to the second chip component so as to have a second inclined surface descending outward from the second chip component;

forming a first interconnecting line to extend from over the first electrode, passing over the first insulating portion, to reach over the interconnecting pattern; and

forming a second interconnecting line to extend from over the second electrode, passing over the second insulating portion, to reach over the interconnecting pattern.

When electrically connecting the first or second electrode to the interconnecting pattern, this embodiment of the present invention enables to avoid heating to a high temperature, such as is carried out in wire bonding or face-down bonding. Therefore, the requirements for heat resistance of the substrate can be reduced, and the generation of stress in the first and second chip components can be reduced. Since the first and second interconnecting lines can be freely formed, the use of a general-purpose substrate is possible.

(10) According to one embodiment of the present invention, there is provided a method of manufacturing an electronic device, comprising:

mounting a first chip component having a first electrode on a substrate in which an interconnecting pattern is formed;

disposing a second chip component having a second electrode, on the side of a surface of the substrate on which the first chip component is mounted, to overlie the first chip component;

forming a first insulating portion of resin laterally to the first chip component;

forming a second insulating portion of resin laterally to the second chip component;

forming a first interconnecting line to extend from over the first electrode, passing over the first insulating portion, to reach over the interconnecting pattern; and

forming a second interconnecting line to extend from over the second electrode, passing over the second insulating portion, and electrically connected to the interconnecting pattern.

When electrically connecting the first or second electrode to the interconnecting pattern, this embodiment of the present invention enables to avoid heating to a high temperature, such as is carried out in wire bonding or face-down bonding. Therefore, the requirements for heat resistance of the substrate can be reduced, and the generation of stress in the first and second chip components can be reduced. Since the first and second interconnecting lines can be freely formed, the use of a general-purpose substrate is possible.

(11) According to one embodiment of the present invention, there is provided a method of manufacturing an electronic device, comprising:

mounting a first chip component having a first electrode on a substrate in which an interconnecting pattern is formed;

disposing a second chip component having a second electrode, on the side of a surface of the substrate on which the first chip component is mounted, to overlie the first chip component;

forming a first insulating portion laterally to the first chip component so as to have a first inclined surface descending outward from the first chip component;

forming a second insulating portion laterally to the second chip component so as to have a second inclined surface descending outward from the second chip component;

forming a first interconnecting line to extend from over the first electrode, passing over the first insulating portion, to reach over the interconnecting pattern; and

forming a second interconnecting line to extend from over the second electrode, passing over the second insulating portion, and electrically connected to the interconnecting pattern.

When electrically connecting the first or second electrode to the interconnecting pattern, this embodiment of the present invention enables to avoid heating to a high temperature, such as is carried out in wire bonding or face-down bonding. Therefore, the requirements for heat resistance of the substrate can be reduced, and the generation of stress in the first and second chip components can be reduced. Since the first and second interconnecting lines can be freely formed, the use of a general-purpose substrate is possible.

(12) The method of manufacturing an electronic device may further comprise forming an insulating layer part of which is interposed between the first and second chip components, wherein:

the second insulating portion may be formed above the insulating layer; and

the second interconnecting line may be formed to pass over the insulating layer.

(13) The method of manufacturing an electronic device may further comprise forming a conductive portion on the interconnecting pattern, wherein the second interconnecting line may be formed to pass over the conductive portion.

(14) The method of manufacturing an electronic device may further comprise forming a penetrating hole in the insulating layer, wherein the conductive portion may be formed in the penetrating hole.

(15) In the method of manufacturing an electronic device, the first and second interconnecting lines may be formed of a dispersing liquid including conductive microparticles.

(16) In the method of manufacturing an electronic device, the steps of forming the first and second interconnecting lines may include ejecting the dispersing liquid including the conductive microparticles.

(17) According to one embodiment of the present invention, there is provided a circuit board on which any of the above described electronic devices is mounted.

(18) According to one embodiment of the present invention, there is provided an electronic instrument comprising any of the above described electronic devices.

The embodiments of the present invention will be described with reference to the drawings.

First Embodiment

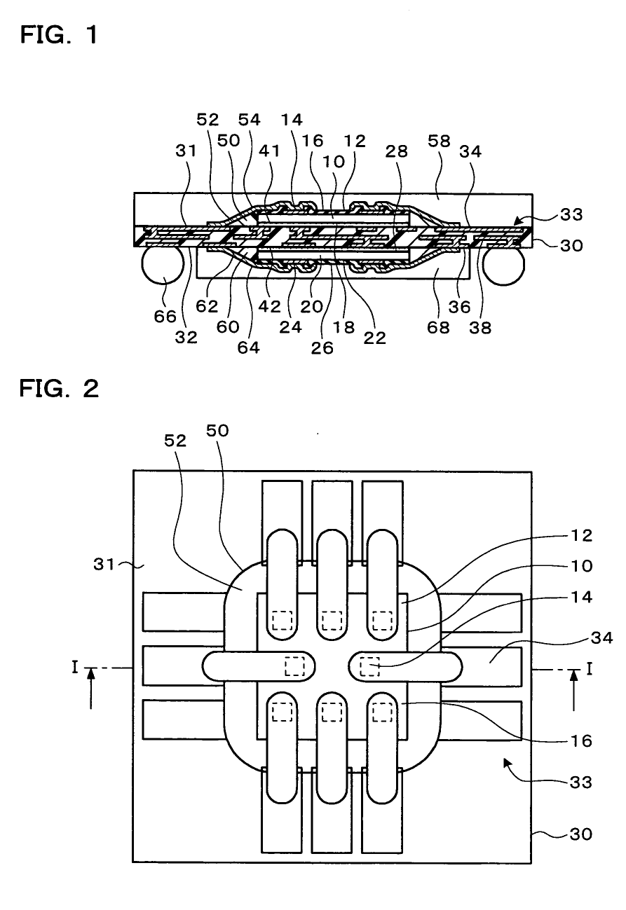

FIG. 1 illustrates an electronic device according to a first embodiment of the present invention, and is a cross-sectional view taken along I-I line in FIG. 2. FIG. 2 is a plan view illustrating the electronic device in this embodiment.

An electronic device has a first chip component 10. The first chip component 10 may be an active component (for example, an integrated circuit component or the like) of a semiconductor component (for example, a semiconductor chip). On the first chip component 10 may be formed an integrated circuit not shown in the drawings. When the first chip component 10 is a semiconductor chip, the electronic device can be referred to as a semiconductor device. The first chip component 10 may also be a passive component (resistor, capacitor, inductor, or the like).

On the upper surface 12 of the first chip component 10, a plurality of first electrodes 14 are formed. The upper surface 12 may be a quadrilateral (for example, a rectangle). The plurality of first electrodes 14 may be formed on the periphery (extremity) of the upper surface 12. For example, the plurality of first electrodes 14 may be disposed along the four sides of the upper surface 12, or may be disposed along two sides. At least one first electrode 14 may be disposed in a central portion of the upper surface 12.

On the upper surface 12, a passivation film 16 formed of at least one layer may be formed. The passivation film 16 is an electrically insulating film. The passivation film 16 may be formed entirely of a non-resin material (for example, SiO₂ or SiN), or may further include a film having a resin (for example, polyimide resin) thereover. In the passivation film 16 is formed an opening, exposing at least a part (for example, a central portion) of the first electrodes 14. That is to say, the passivation film 16 is formed to avoid at least a central portion of the first electrodes 14. The passivation film 16 may be placed on the extremity of the first electrodes 14. The passivation film 16 may cover the entire periphery of the upper surface 12.

On the reverse surface (the surface opposite to the upper surface 12) 18 of the first chip component 10 electrodes are not formed. The reverse surface 18 may be electrically connected to an integrated circuit not shown in the drawings, or may not be connected. On the reverse surface 18, a passivation film (electrically insulating film) may be formed, or may not be formed. The reverse surface 18 may be formed of a semiconductor (or conductor). On the lateral surface (the surface excluding the upper surface 12 and reverse surface 18) of the first chip component 10, a passivation film (electrically insulating film) may be formed, or may not be formed. On the lateral surface of the first chip component 10, electrodes are not formed. The lateral surface of the first chip component 10 may be formed of a semiconductor (or conductor).

The electronic device has a second chip component 20. The second chip component 20 may have an upper surface 22, second electrodes 24, passivation film 26, and reverse surface 28 (to which the respective descriptions of the upper surface 12, first electrodes 14, passivation film 16, and reverse surface 18 of the first chip component 10 apply).

The electronic device has a substrate 30. The substrate 30 has a interconnecting pattern 33. The interconnecting pattern 33 includes a first exposed portion 34 exposed to a first surface 31 of the substrate 30. Over the first exposed portion 34, a first interconnecting line 54 is provided for electrically connecting the first chip component 10 and interconnecting pattern 33. The first exposed portion 34 may have lands (portions wider than the lines) not shown in the drawings. The interconnecting pattern 33 includes a second exposed portion 36 exposed to a second surface 32 of the substrate 30. Over the second exposed portion 36, a second interconnecting line 64 is provided for electrically connecting the second chip component 20 and interconnecting pattern 33. The second exposed portion 36 may have lands (portions wider than the lines) not shown in the drawings.

The substrate 30 on which the interconnecting pattern 33 is formed may be referred as a wiring board. The wiring board may be a multi-layer substrate (including a double-sided substrate). A multi-layer substrate includes multiple layers (two or more layers) of conductive pattern. The interconnecting pattern 33 may include a conductive pattern 38 incorporated into the substrate 30. The wiring board may be a wiring board having internal components. More specifically, within the substrate 30 passive components such as resistors, capacitors, inductors, or the like, or active components such as integrated circuit components may be electrically connected to the conductive pattern 38. Alternatively, by forming a part of the conductive pattern 38 of a material with a high resistance value, a resistor may be formed.

The first chip component 10 is mounted on the substrate 30. The reverse surface 18 of the first chip component 10 opposes the substrate 30 (more specifically, the first surface 31 thereof). Between the first chip component 10 and the substrate 30 may be interposed a first adhesive layer 41. The first adhesive layer 41 may be formed of an adhesive. If the first adhesive layer 41 is electrically conductive, the first exposed portion 34 and the reverse surface 18 of the first chip component 10 can be electrically connected. If the first adhesive layer 41 is electrically insulating, the first exposed portion 34 and the reverse surface 18 of the first chip component 10 can be electrically insulated. The first adhesive layer 41 may be formed of an electrically insulating resin in which conductive particles are dispersed.

On the substrate 30 is mounted the second chip component 20. The reverse surface 28 of the second chip component 20 opposes the substrate 30 (more specifically, the second surface 32 thereof). Between the second chip component 20 and the substrate 30 may be interposed a second adhesive layer 42. The second adhesive layer 42 may be formed of an adhesive. If the second adhesive layer 42 is electrically conductive, the second exposed portion 36 and the reverse surface 28 of the second chip component 20 can be electrically connected. If the second adhesive layer 42 is electrically insulating, the second exposed portion 36 and the reverse surface 28 of the second chip component 20 can be electrically insulated. The second adhesive layer 42 may be formed of an electrically insulating resin in which conductive particles are dispersed.

The electronic device has a first insulating portion 50. The first insulating portion 50 is formed of an electrically insulating material (for example, resin). The first insulating portion 50 may be formed of a different material from the first adhesive layer 41. The first insulating portion 50 is provided adjacent to the first chip component 10. The first insulating portion 50 may be provided to surround the first chip component 10, or may be provided only adjacent to the first electrodes 14 of the first chip component 10. The first insulating portion 50 may contact the lateral surface of the first chip component 10. That is to say, the formation may be such that there is no gap between the first insulating portion 50 and the first chip component 10. In the example shown in FIG. 1, the first insulating portion 50 is provided so as not to exceed the height of the first chip component 10. The upper extremity of the first insulating portion 50 may be of the same height as the upper surface (surface of the passivation film 16) of the first chip component 10. In this case, there is no height discrepancy between the first insulating portion 50 and the first chip component 10. The portion of the lateral surface of the first chip component 10 formed from the semiconductor or conductor may alone be covered by the first insulating portion 50. In this case, the upper extremity of the first insulating portion 50 is lower than the upper surface of the passivation film 16.

The first insulating portion 50 has a first inclined surface 52 descending outward from the first chip component 10. The thickest portion of the first insulating portion 50 is positioned closest to the first chip component 10, and the thinnest portion is positioned furthest away from the first chip component 10. The first insulating portion 50 may be formed over a part of the interconnecting pattern 33 (more specifically, the first exposed portion 34 thereof).

The electronic device has a second insulating portion 60. The second insulating portion 60 is formed of an electrically insulating material (for example, resin). The second insulating portion 60 may be formed of a different material from the second adhesive layer 42. The second insulating portion 60 is provided adjacent to the second chip component 20. The second insulating portion 60 may be provided to surround the second chip component 20, or may be provided only adjacent to the second electrodes 24 of the second chip component 20. The second insulating portion 60 may contact the lateral surface of the second chip component 20. That is to say, the formation may be such that there is no gap between the second insulating portion 60 and the second chip component 20. In the example shown in FIG. 1, the second insulating portion 60 is provided so as not to exceed the height of the second chip component 20. The upper extremity of the second insulating portion 60 may be of the same height as the upper surface (surface of the passivation film 26) of the second chip component 20. In this case, there is no height discrepancy between the second insulating portion 60 and the second chip component 20. The portion of the lateral surface of the second chip component 20 formed from the semiconductor or conductor may alone be covered by the second insulating portion 60. In this case, the upper extremity of the second insulating portion 60 is lower than the upper surface of the passivation film 26.

The second insulating portion 60 has a second inclined surface 62 descending outward from the second chip component 20. The thickest portion of the second insulating portion 60 is positioned closest to the second chip component 20, and the thinnest portion is positioned furthest away from the second chip component 20. The second insulating portion 60 may be formed over a part of the interconnecting pattern 33 (more specifically, the second exposed portion 36 thereof).

The electronic device has the first interconnecting line 54. A part of the first interconnecting line 54 is formed over the first electrodes 14. The first interconnecting line 54 may pass over the passivation film 16. The first interconnecting line 54 passes over the first insulating portion 50. When the first insulating portion 50 is formed of resin, the degree of intimate contact of the first insulating portion 50 and the first interconnecting line 54 is higher than the degree of intimate contact of the passivation film 16 and first interconnecting line 54. If the height discrepancy between the first chip component 10 (for example, the passivation film 16 thereof) and the first insulating portion 50 is small, breaking of the first interconnecting line 54 can be prevented. The first interconnecting line 54 is formed to extend over the interconnecting pattern 33 (more specifically, the first exposed portion 34 thereof). That is to say, the first interconnecting line 54 electrically connects the first electrodes 14 and the interconnecting pattern 33.

The electronic device has the second interconnecting line 64. A part of the second interconnecting line 64 is formed over the second electrodes 24. The second interconnecting line 64 may pass over the passivation film 26. The second interconnecting line 64 passes over the second insulating portion 60. When the second insulating portion 60 is formed of resin, the degree of intimate contact of the second insulating portion 60 and second interconnecting line 64 is higher than the degree of intimate contact of passivation film 26 and second interconnecting line 64. If the height discrepancy between the second chip component 20 (for example, the passivation film 26 thereof) and the second insulating portion 60 is small, breaking of the second interconnecting line 64 can be prevented. The second interconnecting line 64 is formed to extend over the interconnecting pattern 33 (more specifically, the second exposed portion 36 thereof). That is to say, the second interconnecting line 64 electrically connects the second electrodes 24 and the interconnecting pattern 33.

The electronic device may have a plurality of external terminals 66. The external terminals 66 may be provided over the interconnecting pattern 33 (for example, the second exposed portion 36). The external terminals 66 may be formed from a soldering material. The soldering material is an electrically conductive metal (for example, an alloy), which is fused to achieve an electrical connection. The soldering material may be either of soft solder or hard solder. As the soldering material may be used solder with no lead content (referred to hereafter as lead-free solder). As the lead-free solder may be used a tin-silver (Sn—Ag), tin-bismuth (Sn—Bi), tin-zinc (Sn—Zn), or tin-copper (Sn—Cu) alloy, or to these alloys at least one of silver, bismuth, zinc, and copper may be further added.

A BGA (Ball Grid Array) type package or CSP (Chip Size Package) and the like having the external terminals 66 are known. Alternatively, an LGA (Land Grid Array) type of package is also known, in which, without providing the external terminals 66, a part of the interconnecting pattern 33 (for example, the second exposed portion 36) forms a portion for external electrical connection.

The electronic device may have a first sealing material 58. The first sealing material 58 seals at least the electrical connection between the first interconnecting line 54 and the first electrodes 14, and the electrical connection between the first interconnecting line 54 and the interconnecting pattern 33. The first sealing material 58 may seal the first chip component 10.

The electronic device may have a second sealing material 68. The second sealing material 68 seals at least the electrical connection between the second interconnecting line 64 and the second electrodes 24, and the electrical connection between the second interconnecting line 64 and the interconnecting pattern 33. The second sealing material 68 may seal the second chip component 20.

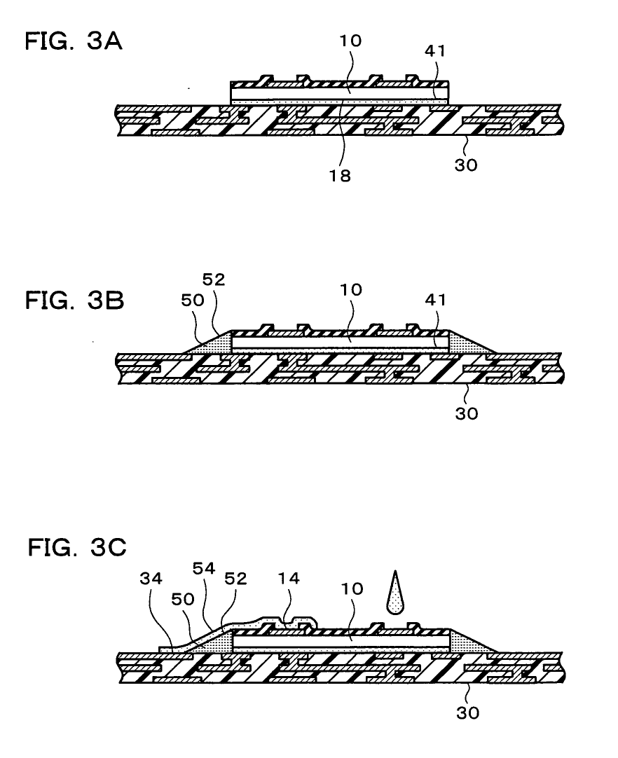

FIGS. 3A to 3C illustrate a method of manufacturing an electronic device according to this embodiment. As shown in FIG. 3A, the first chip component 10 is mounted on the substrate 30. More specifically, the first chip component 10 is mounted with its reverse surface 18 opposing the first surface 31 of the substrate 30. An adhesive may be introduced between the substrate 30 and the first chip component 10, to form the first adhesive layer 41.

As shown in FIG. 3B, the first insulating portion 50 is formed adjacent to the first chip component 10. The first insulating portion 50 may be formed by providing a material distinct from the adhesive of which the first adhesive layer 41 is formed. The first insulating portion 50 may be formed of a resin such as polyimide resin, silicone-modified polyimide resin, epoxy resin, silicone-modified epoxy resin, benzocyclobutene (BCB), polybenzoxazole (PBO), and so forth. The insulating portion 50 may be formed by potting with a liquid resin, or may be formed by affixing a dry film. The first insulating portion 50 is formed to have the first inclined surface 52 descending outward from the first chip component 10. The first insulating portion 50 may be formed so as to contact the lateral surface of the first chip component 10.

As shown in FIG. 3C, the first interconnecting line 54 is formed. The first interconnecting line 54 is formed to extend from over the first electrodes 14, passing over the first insulating portion 50, to reach over the interconnecting pattern 33 (for example, the first exposed portion 34). The first interconnecting line 54 may be formed from a dispersing liquid including conductive microparticles. For example, an ink-jet method may be applied. More specifically, the dispersing liquid including conductive microparticles may be ejected over the first electrodes 14, the first insulating portion 50, and the interconnecting pattern 33 (for example, the first exposed portion 34), to form the first interconnecting line 54. The process of forming the first interconnecting line 54 may include drying the dispersing liquid including conductive microparticles to eliminate the dispersant. The process of forming the first interconnecting line 54 may include applying heat to a coating material covering the conductive microparticles, to cause breakdown. The process of forming the first interconnecting line 54 may include polymerizing the conductive microparticles together. The conductive microparticles may be nanoparticles. In this case, the volume resistivity of the dispersing liquid can be reduced.

On the second surface 32 of the substrate 30, the same process as described above is carried out. That is to say, as shown in FIG. 1, the second chip component 20 is mounted on the substrate 30. More specifically, the second chip component 20 is mounted with its reverse surface 28 opposing the second surface 32 of the substrate 30. An adhesive may be introduced between the substrate 30 and the second chip component 20, to form the second adhesive layer 42.

The second insulating portion 60 is formed adjacent to the second chip component 20. The second insulating portion 60 may be formed by providing a material distinct from the adhesive of which the second adhesive layer 42 is formed. The second insulating portion 60 may be formed of a resin such as polyimide resin, silicone-modified polyimide resin, epoxy resin, silicone-modified epoxy resin, benzocyclobutene (BCB), polybenzoxazole (PBO), and so forth. The insulating portion 60 may be formed by potting with a liquid resin, or may be formed by affixing a dry film. The second insulating portion 60 is formed to have the second inclined surface 62 descending outward from the second chip component 20. The second insulating portion 60 may be formed so as to contact the lateral surface of the second chip component 20.

Next, the second interconnecting line 64 is formed. The second interconnecting line 64 is formed to extend from over the second electrodes 24, passing over the second insulating portion 60, to reach over the interconnecting pattern 33 (for example, the second exposed portion 36). The second interconnecting line 64 may be formed from a dispersing liquid including conductive microparticles. For example, an inkjet method may be applied. More specifically, the dispersing liquid including conductive microparticles may be ejected over the second electrodes 24, the second insulating portion 60, and the interconnecting pattern 33 (for example, the second exposed portion 36), to form the second interconnecting line 64. The process of forming the second interconnecting line 64 may include drying the dispersing liquid including conductive microparticles to eliminate the dispersant. The process of forming the second interconnecting line 64 may include applying heat to a coating material covering the conductive microparticles, to cause breakdown. The process of forming the second interconnecting line 64 may include polymerizing the conductive microparticles together. The conductive microparticles may be nanoparticles. In this case, the volume resistivity of the dispersing liquid can be reduced.

As shown in FIG. 1, at least one of first and second sealing materials 58 and 68 may be provided. At least one of the first and second sealing materials 58 and 68 can be formed by a transfer mold or potting. At least one of the first and second sealing materials 58 and 68 may be omitted.

According to this embodiment, when electrically connecting the first and second electrodes 14 and 24 to the interconnecting pattern 33, the application of high temperatures as in wire bonding or face-down bonding can be avoided. Therefore, the requirements for heat resistance of the substrate 30 can be reduced, and the generation of stress in the first and second chip components 10 and 20 reduced. Using a general-purpose substrate for the substrate 30, the first and second connecting lines 54 and 64 can be led out depending on the first and second chip components 10 and 20 (the layout and so forth of the first and second electrodes 14 and 24). In this case, depending on the type of the first and second chip components 10 and 20, the first and second connecting lines 54 and 64 can be connected to different parts of the interconnecting pattern 33.

Second Embodiment

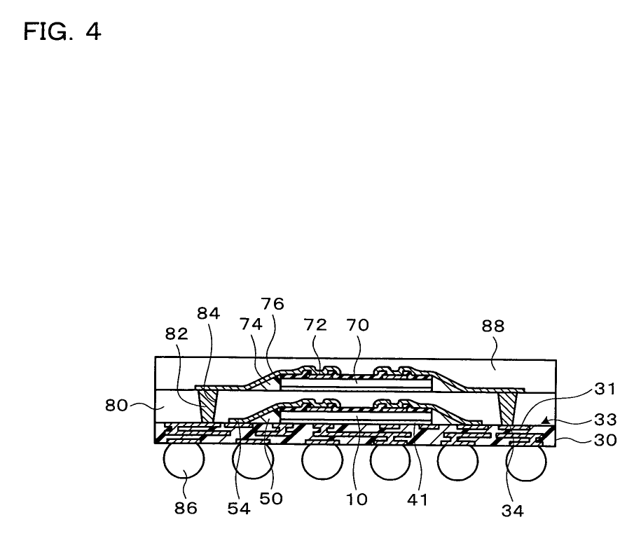

FIG. 4 illustrates an electronic device according to a second embodiment of the present invention. The electronic device shown in FIG. 4 includes the first chip component 10, substrate 30, first adhesive layer 41, first insulating portion 50 and first interconnecting line 54 described in the first embodiment.

In this embodiment, there is a second chip component 70 disposed so as to overlie the first chip component 10 on the side of the first surface 31. The second chip component 70 has a second electrode 72. For other detailed aspects of the second chip component 70, the description of the second chip component 20 in the first embodiment applies.

The electronic device has a second insulating portion 74. To the second insulating portion 74, the description of the second insulating portion 60 in the first embodiment applies. To the relationship between the second insulating portion 74 and the second chip component 70, the description of the relationship between the second chip component 20 and the second insulating portion 60 in the first embodiment applies.

The electronic device has a second interconnecting line 76. To the second interconnecting line 76, the description of the second interconnecting line 64 in the first embodiment applies. To the relationship between the second interconnecting line 76 and the second insulating portion 74 and second chip component 70, the description of the relationship of the second interconnecting line 64 and the second insulating portion 60 and second chip component 20 in the first embodiment applies.

The electronic device has an insulating layer 80, part of which is interposed between the first and second chip components 10 and 70. To the insulating layer 80, the description of the first sealing material 58 in the first embodiment may be applied. The second insulating portion 74 is formed over the insulating layer 80. The second interconnecting line 76 is formed to pass over the insulating layer 80.

The electronic device has a conductive portion 82 interposed between the second interconnecting line 76 and the interconnecting pattern 33 (for example, the first exposed portion 34). A penetrating hole 84 may be formed in the insulating layer 80, and the conductive portion 82 formed in the penetrating hole 84. By means of the conductive portion 82, the second interconnecting line 76 and the interconnecting pattern 33 (for example, the first exposed portion 34) are electrically connected.

The electronic device may have a second sealing material 88. To the second sealing material 88, the description of the second sealing material 68 in the first embodiment applies. In other respects, the description in the first embodiment applies also to this embodiment. The electronic device may have a plurality of external terminals 86. To the external terminals 86, the description of the external terminals 66 in the first embodiment applies.

In this embodiment, the first and second chip components 10 and 70 are disposed so as to be overlying, and further at least one (or a plurality of) third chip component(s) may be provided to overlie the second chip component 70. To the third chip component, the description of the second chip component 70 applies. The content of this embodiment may be combined with the content of the first embodiment.

For the method of manufacture of this embodiment of the electronic device, including content that can be derived from the structure of the above described electronic device, the description of the method of manufacture in the first embodiment may be applied. In this embodiment too, the effect described in the first embodiment can be obtained.

Modifications

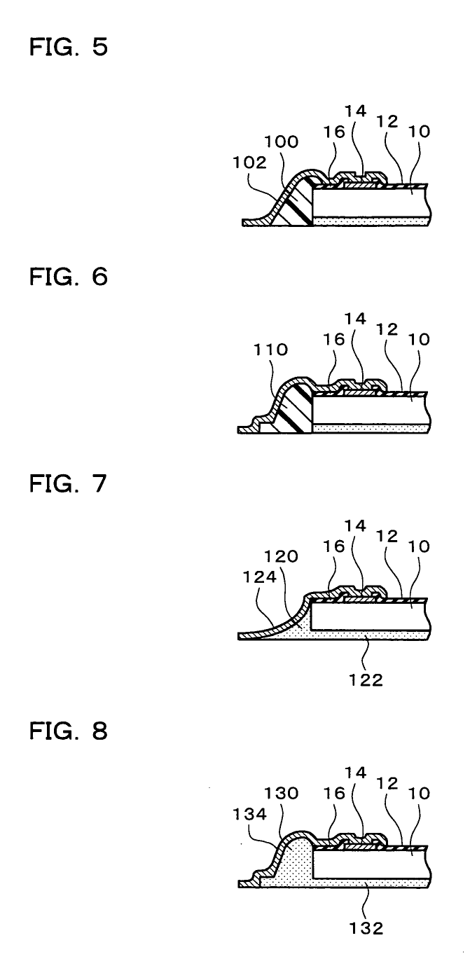

FIGS. 5 to 12 illustrate modifications of the electronic device according to the first and second embodiments of the present invention. In the following description, the first chip component 10 may be replaced by the second chip component 20 or 70, and the first insulating portion 100, 110, 120, 130, or 145 may be replaced by the second insulating portion 60 or 74.

In FIG. 5, a first insulating portion 100 is formed so that part thereof is mounted on the upper surface 12 (more specifically, the passivation film 16) of the first chip component 10. A part of the first insulating portion 100 is placed on a portion more on the periphery than the first electrodes 14 of the first chip component 10. To prevent the first electrodes 14 being covered by the first insulating portion 100, the first insulating portion 100 may be provided only as far as a position remote from the first electrodes 14 (a position on the peripheral side of the electrodes). Alternatively, the first insulating portion 100 may be formed so as to be adjacent to the portion of first electrodes 14 exposed from the passivation film 16. In this case, an interconnecting line 102 is not provided over the passivation film 16 having a low degree of intimate contact therewith. The first insulating portion 100 has a portion adjacent to the first chip component 10, and rising above the upper surface 12. To other aspects of the construction, the same content as the electronic device shown in FIG. 1 applies.

In FIG. 6, a first insulating portion 110 is formed so that a part thereof is not formed on the upper surface 12 of the first chip component 10. The first insulating portion 110 has a portion adjacent to the first chip component 10, and rising above the upper surface 12. The first insulating portion 110 has a step portion on the opposite side from the first chip component 10. To other aspects of the construction, the same content as the electronic device shown in FIG. 1 applies.

In FIG. 7, a first insulating portion 120 and a first adhesive layer 122 are formed integrally. The first adhesive layer 122 is formed of the same material as the first insulating portion 120. An insulating adhesive may be introduced between the substrate 30 and the first chip component 10, compressive force applied between the substrate 30 and the first chip component 10, the adhesive squeezed out to the neighborhood of the first chip component 10, and the first insulating portion 120 and first adhesive layer 122 formed from the adhesive. A first inclined surface 124 of the first insulating portion 120 is concave (for example, a concave surface describing an arc in a section perpendicular to the upper surface 12). To other aspects of the construction, the same content as the electronic device shown in FIG. 1 applies. The content shown in FIG. 7 may be applied to other embodiments or modifications.

In FIG. 8, a first insulating portion 130 and a first adhesive layer 132 are formed integrally. The first adhesive layer 132 is formed of the same material as the first insulating portion 130. An insulating adhesive may be introduced between the substrate 30 and the first chip component 10, compressive force applied between the substrate 30 and the first chip component 10, the adhesive squeezed out to the neighborhood of the first chip component 10, and the first insulating portion 130 and first adhesive layer 132 formed from the adhesive. A first inclined surface 134 of the first insulating portion 130 is convex (for example, a convex surface describing an arc in a section perpendicular to the upper surface 12). To other aspects of the construction, the same content as the electronic device shown in FIG. 1 applies. The content shown in FIG. 8 may be applied to other embodiments or modifications.

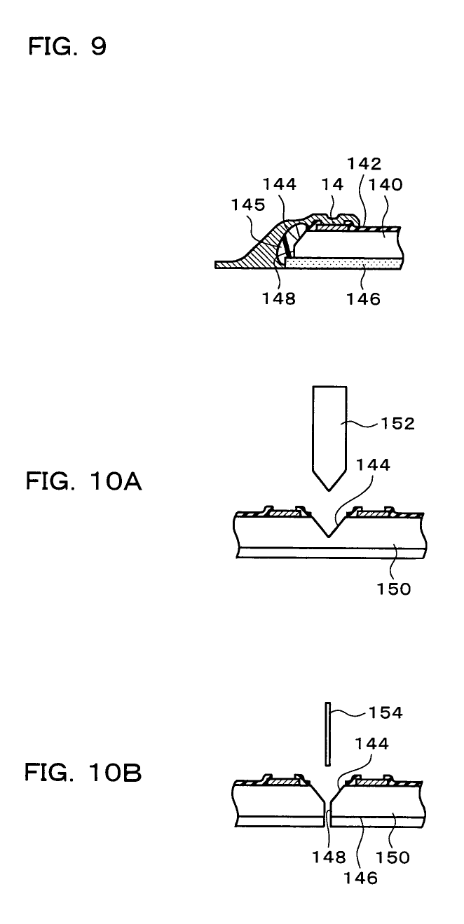

In FIG. 9, a first chip component 140 has a lateral surface 144 inclined to descend outward from a first surface (the surface on which the first electrodes 14 are formed) 142. Since the lateral surface 144 is inclined, a first insulating portion 145 thereover can easily be provided to have an inclined surface. The first chip component 140 may include a lateral surface 148 perpendicular to a second surface 146 being opposite to the first surface 142. The lateral surfaces 144 and 148 may be connected. To other aspects of the construction, the same content as the electronic device shown in FIG. 1 applies. The content shown in FIG. 9 may be applied to other embodiments or modifications.

The lateral surface 144 may be formed as shown in FIG. 10A, when a wafer (for example, a semiconductor wafer) 150 is cut. More specifically, using a cutter (for example, a dicing saw) 152 having two cutting surfaces meeting at an angle, as in an angled milling tool, a groove (for example, a V-shaped groove) having inclined surfaces may be formed in the wafer 150, and by means of the inclined surfaces the lateral surface 144 may be formed. After forming the groove, as shown in FIG. 10B, the bottom surface of the groove may be separated with a cutter (for example, a dicing saw) 154 having a cutting edge on the peripheral surface. In this way, the lateral surface 148 being perpendicular to the second surface 146 can be formed.

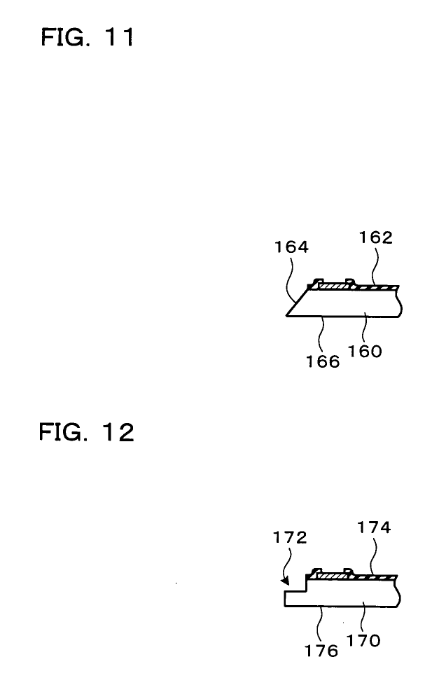

In FIG. 11, a lateral surface 164 of a first chip component 160 is inclined to descend outward from a first surface (the surface on which the first electrodes 14 are formed) 162. The lateral surface 164 is also inclined from a second surface 166 opposite to the first surface 162. To other aspects of the construction, the same content as the electronic device shown in FIG. 1 applies. The content shown in FIG. 11 may be applied to other embodiments or modifications.

In FIG. 12, a first chip component 170 has a step 172 at its extremity. The step 172 includes a surface descending from a first surface (the surface on which the first electrodes are formed) 174 (for example, descending vertically), a surface rising from a second surface 176 on the side opposite to the first surface 174 (for example, rising vertically), and a surface joining these surface and extending horizontally (for example, in a direction parallel to the first or second surface 174 or 176). To other aspects of the construction, the same content as the electronic device shown in FIG. 1 applies. The content shown in FIG. 12 may be applied to other embodiments or modifications.

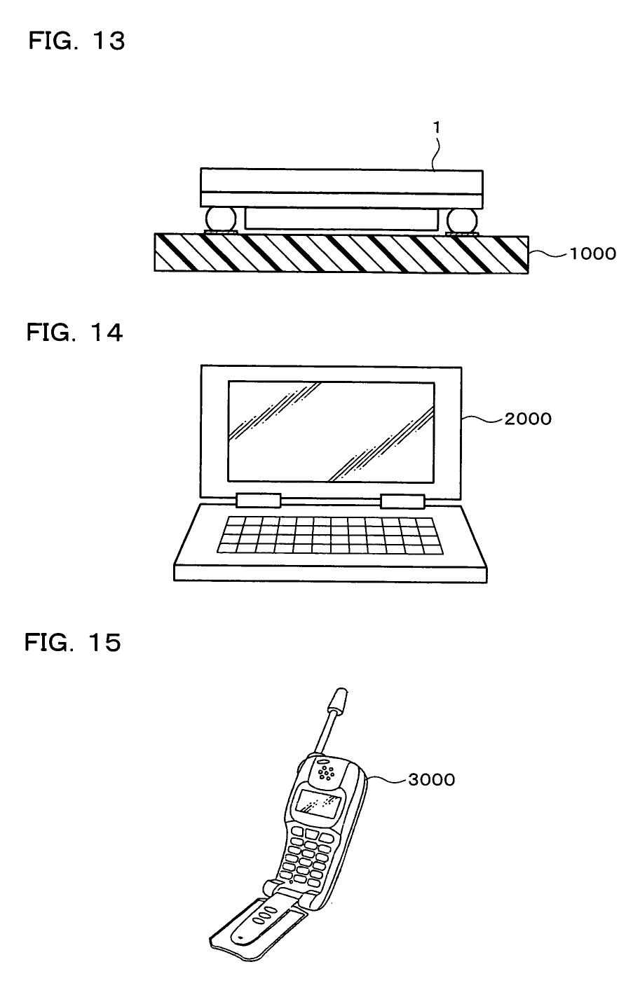

FIG. 13 shows a circuit board 1000 on which is mounted the electronic device 1 of the above described embodiments. As electronic instruments having this electronic device, FIG. 14 shows a notebook personal computer 2000, and FIG. 15 shows a mobile telephone 3000.

The present invention is not limited to the above-described embodiments, and various modifications can be made. For example, the present invention includes various other configurations substantially the same as the configurations described in the embodiments (in function, method and effect, or in objective and effect, for example). The present invention also includes a configuration in which an unsubstantial portion in the described embodiments is replaced. The present invention also includes a configuration having the same effects as the configurations described in the embodiments, or a configuration able to achieve the same objective. Further, the present invention includes a configuration in which a publicly known technique is added to the configurations in the embodiments.

What is claimed is:

1. An electronic device comprising:
a substrate having an interconnecting pattern;
a first chip component which has a first electrode and is mounted on a first surface of the substrate;
a second chip component which has a second electrode and is mounted on a second surface of the substrate;
a first insulating portion which is formed of resin and disposed laterally to the first chip component;
a second insulating portion which is formed of resin and disposed laterally to the second chip component;
a first interconnecting line formed to extend from over the first electrode, passing over the first insulating portion, to reach over the interconnecting pattern; and
a second interconnecting line formed to extend from over the second electrode, passing over the second insulating portion, to reach over the interconnecting pattern.

2. An electronic device comprising:
a substrate having an interconnecting pattern;
a first chip component which has a first electrode and is mounted on a first surface of the substrate;
a second chip component which has a second electrode and is mounted on a second surface of the substrate;
a first insulating portion which is disposed laterally to the first chip component and has a first inclined surface descending outward from the first chip component;
a second insulating portion which is disposed laterally to the second chip component and has a second inclined surface descending outward from the second chip component;
a first interconnecting line formed to extend from over the first electrode, passing over the first insulating portion, to reach over the interconnecting pattern; and
a second interconnecting line formed to extend from over the second electrode, passing over the second insulating portion, to reach over the interconnecting pattern.

3. An electronic device comprising:
a substrate having an interconnecting pattern;
a first chip component which has a first electrode and is mounted on the substrate;
a second chip component which has a second electrode and is disposed on the side of a surface of the substrate on which the first chip component is mounted, to overlie the first chip component;
a first insulating portion which is formed of resin and disposed laterally to the first chip component;
a second insulating portion which is formed of resin and disposed laterally to the second chip component;
a first interconnecting line formed to extend from over the first electrode, passing over the first insulating portion, to over the interconnecting pattern; and
a second interconnecting line formed to extend from over the second electrode, passing over the second insulating portion, and electrically connected to the interconnecting pattern.

4. The electronic device as defined in claim 3, further comprising:
an insulating layer part of which is interposed between the first and second chip components, wherein:
the second insulating portion is formed above the insulating layer; and
the second interconnecting line is formed to pass over the insulating layer.

5. The electronic device as defined in claim 3, further comprising:
a conductive portion interposed between the second interconnecting line and the interconnecting pattern.

6. The electronic device as defined in claim 4, further comprising:
a conductive portion interposed between the second interconnecting line and the interconnecting pattern.

7. The electronic device as defined in claim 6,
wherein a penetrating hole is formed in the insulating layer, and the conductive portion is formed in the penetrating hole.

8. An electronic device comprising:
a substrate having an interconnecting pattern;
a first chip component which has a first electrode and is mounted on the substrate;
a second chip component which has a second electrode and is disposed on the side of a surface of the substrate on which the first chip component is mounted, to overlie the first chip component;
a first insulating portion which is disposed laterally to the first chip component and has a first inclined surface descending outward from the first chip component;
a second insulating portion which is disposed laterally to the second chip component and has a second inclined surface descending outward from the second chip component;
a first interconnecting line formed to extend from over the first electrode, passing over the first insulating portion, to over the interconnecting pattern; and
a second interconnecting line formed to extend from over the second electrode, passing over the second insulating portion, and electrically connected to the interconnecting pattern.

9. The electronic device as defined in claim 8, further comprising:
an insulating layer part of which is interposed between the first and second chip components, wherein:
the second insulating portion is formed above the insulating layer; and
the second interconnecting line is formed to pass over the insulating layer.

10. The electronic device as defined in claim 8, further comprising:
a conductive portion interposed between the second interconnecting line and the interconnecting pattern.

11. The electronic device as defined in claim 9, further comprising:
a conductive portion interposed between the second interconnecting line and the interconnecting pattern.

12. The electronic device as defined in claim 11,
wherein a penetrating hole is formed in the insulating layer, and the conductive portion is formed in the penetrating hole.

13. A method of manufacturing an electronic device, comprising:
mounting a first chip component having a first electrode on a first surface of a substrate in which an interconnecting pattern is formed;
mounting a second chip component having a second electrode on a second surface of the substrate;
forming a first insulating portion of resin laterally to the first chip component;
forming a second insulating portion of resin laterally to the second chip component;
forming a first interconnecting line to extend from over the first electrode, passing over the first insulating portion, to reach over the interconnecting pattern; and
forming a second interconnecting line to extend from over the second electrode, passing over the second insulating portion, to reach over the interconnecting pattern.

14. The method of manufacturing an electronic device as defined in claim 13,
wherein the first and second interconnecting lines are formed of a dispersing liquid including conductive microparticles.

15. The method of manufacturing an electronic device as defined in claim 14,
wherein the steps of forming the first and second interconnecting lines includes ejecting the dispersing liquid including the conductive microparticles.

16. A method of manufacturing an electronic device, comprising:
mounting a first chip component having a first electrode on a first surface of a substrate in which an interconnecting pattern is formed;
mounting a second chip component having a second electrode on a second surface of the substrate;
forming a first insulating portion laterally to the first chip component so as to have a first inclined surface descending outward from the first chip component;
forming a second insulating portion laterally to the second chip component so as to have a second inclined surface descending outward from the second chip component;
forming a first interconnecting line to extend from over the first electrode, passing over the first insulating portion, to reach over the interconnecting pattern; and
forming a second interconnecting line to extend from over the second electrode, passing over the second insulating portion, to reach over the interconnecting pattern.

17. The method of manufacturing an electronic device as defined in claim 16,
wherein the first and second interconnecting lines are formed of a dispersing liquid including conductive microparticles.

18. The method of manufacturing an electronic device as defined in claim 17,
wherein the steps of forming the first and second interconnecting lines includes ejecting the dispersing liquid including the conductive microparticles.

19. A method of manufacturing an electronic device, comprising:
mounting a first chip component having a first electrode on a substrate in which an interconnecting pattern is formed;
disposing a second chip component having a second electrode, on the side of a surface of the substrate on which the first chip component is mounted, to overlie the first chip component;
forming a first insulating portion of resin laterally to the first chip component;
forming a second insulating portion of resin laterally to the second chip component;
forming a first interconnecting line to extend from over the first electrode, passing over the first insulating portion, to reach over the interconnecting pattern; and
forming a second interconnecting line to extend from over the second electrode, passing over the second insulating portion, and electrically connected to the interconnecting pattern.

20. The method of manufacturing an electronic device as defined in claim 19, further comprising:
forming an insulating layer part of which is interposed between the first and second chip components, wherein:
the second insulating portion is formed above the insulating layer; and
the second interconnecting line is formed to pass over the insulating layer.

21. The method of manufacturing an electronic device as defined in claim 19, further comprising:
forming a conductive portion on the interconnecting pattern,
wherein the second interconnecting line is formed to pass over the conductive portion.

22. The method of manufacturing an electronic device as defined in claim 20, further comprising:
forming a conductive portion on the interconnecting pattern,
wherein the second interconnecting line is formed to pass over the conductive portion.

23. The method of manufacturing an electronic device as defined in claim 22, further comprising:
forming a penetrating hole in the insulating layer,
wherein the conductive portion is formed in the penetrating hole.

24. The method of manufacturing an electronic device as defined in claim 19,
wherein the first and second interconnecting lines are formed of a dispersing liquid including conductive microparticles.

25. The method of manufacturing an electronic device as defined in claim 24,
wherein the steps of forming the first and second interconnecting lines includes ejecting the dispersing liquid including the conductive microparticles.

26. A method of manufacturing an electronic device, comprising:
mounting a first chip component having a first electrode on a substrate in which an interconnecting pattern is formed;
disposing a second chip component having a second electrode, on the side of a surface of the substrate on which the first chip component is mounted, to overlie the first chip component;
forming a first insulating portion laterally to the first chip component so as to have a first inclined surface descending outward from the first chip component;
forming a second insulating portion laterally to the second chip component so as to have a second inclined surface descending outward from the second chip component;
forming a first interconnecting line to extend from over the first electrode, passing over the first insulating portion, to reach over the interconnecting pattern; and
forming a second interconnecting line to extend from over the second electrode, passing over the second insulating portion, and electrically connected to the interconnecting pattern.

27. The method of manufacturing an electronic device as defined in claim 26, further comprising:
forming an insulating layer part of which is interposed between the first and second chip components, wherein:
the second insulating portion is formed above the insulating layer; and
the second interconnecting line is formed to pass over the insulating layer.

28. The method of manufacturing an electronic device as defined in claim 26, further comprising:
forming a conductive portion on the interconnecting pattern,
wherein the second interconnecting line is formed to pass over the conductive portion.

29. The method of manufacturing an electronic device as defined in claim 27, further comprising:
forming a conductive portion on the interconnecting pattern,
wherein the second interconnecting line is formed to pass over the conductive portion.

30. The method of manufacturing an electronic device as defined in claim 29, further comprising:
forming a penetrating hole in the insulating layer,
wherein the conductive portion is formed in the penetrating hole.

31. The method of manufacturing an electronic device as defined in claim 26,
wherein the first and second interconnecting lines are formed of a dispersing liquid including conductive microparticles.

32. The method of manufacturing an electronic device as defined in claim 31,
wherein the steps of forming the first and second interconnecting lines includes ejecting the dispersing liquid including the conductive microparticles.

33. A circuit board on which the electronic device as defined in claim 1 is mounted.

34. A circuit board on which the electronic device as defined in claim 2 is mounted.

35. A circuit board on which the electronic device as defined in claim 3 is mounted.

36. A circuit board on which the electronic device as defined in claim 8 is mounted.

37. An electronic instrument comprising the electronic device as defined in claim 1.

38. An electronic instrument comprising the electronic device as defined in claim 2.

39. An electronic instrument comprising the electronic device as defined in claim 3.

40. An electronic instrument comprising the electronic device as defined in claim 8.
